(19) United States
(12) Patent Application Publication
(10) Pub. No.: US 2026/0314467 A1
(43) Pub. Date: Oct. 8, 2026

(54) LOW RESISTANCE STRUCTURES IN SYSTEMS

(71) Applicant: Micron Technology, Inc., Boise, ID (US)

(72) Inventors: Bharat Bhushan, Boise, ID (US); Fuad Badrieh, Boise, ID (US); Mark Zaleski, Boise, ID (US); Kunal R. Parekh, Boise, ID (US); Keizo Kawakita, Hiroshima (JP); Akshay N. Singh, Boise, ID (US)

(21) Appl. No.: 19/633,750

(22) Filed: Mar. 30, 2026

Related U.S. Application Data
(60) Provisional application No. 63/783,293, filed on Apr. 4, 2025.

(51) Int. Cl. H10W 72/90; H10W 20/20; H10W 20/43

(52) U.S. Cl. CPC H10W 72/9226; H10W 20/212; H10W 20/2134; H10W 20/43; H10W 72/932

(57) ABSTRACT

Methods, systems, and devices for low resistance structures in systems are described. The described techniques provide for various structures of a power delivery network (PDN), each associated with a reduced resistance relative to other PDN structures. The PDN may include multiple through silicon vias (TSVs) having a relatively small footprint coupled with a metallic pad, where the TSVs may have a relatively small pitch between adjacent ones of the TSVs. In some examples, the PDN structure may include layers between the multiple TSVs and the metallic pad, where each metal layer may be separated by a respective set of vias including various conductive materials. In some other examples, the PDN structure may include a through dielectric via (TDV) between the TSVs and the metallic pad or may include respective sets of metal bars between metallic pads coupled with the TSVs.

### CROSS REFERENCE

The present Application for Patent claims priority to U.S. Patent Application No. 63/783,293 by Bhushan et al., entitled “LOW RESISTANCE STRUCTURES IN SYSTEMS,” filed Apr. 4, 2025, which is assigned to the assignee hereof, and which is expressly incorporated by reference in its entirety herein.

### TECHNICAL FIELD

The following relates to one or more systems for memory, including low resistance structures in systems.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports low resistance structures in systems in accordance with examples as disclosed herein.

FIGS. 2A through 2E show examples of devices that support low resistance structures in systems in accordance with examples as disclosed herein.

FIGS. 3A and 3B show examples of devices that support low resistance structures in systems in accordance with examples as disclosed herein.

FIGS. 4A through 4C show examples of devices that support low resistance structures in systems in accordance with examples as disclosed herein.

### DETAILED DESCRIPTION

Some semiconductor systems (e.g., memory systems, processor systems, systems having a combination of memory and processing) may include a stack of semiconductor components (e.g., semiconductor dies), which may include one or more memory dies (e.g., memory dies, array dies, memory array dies) or one or more stacks of memory dies that are stacked with a logic die that is operable to access a set of memory arrays distributed across the one or more memory dies. Such a stacked architecture may be implemented as part of a high bandwidth memory (HBM) system or a dynamic random access memory (DRAM) system, among other examples, and may support solutions for memory-centric logic, such as graphics processing units (GPUs), among other implementations. In some examples, an HBM system may include one or more memory dies coupled (e.g., bonded, stacked) with a logic die. In some examples, a DRAM system may be closely coupled (e.g., physically coupled, electrically coupled, directly coupled) with a processor, such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

In some examples, the stack of semiconductor dies may include a power delivery network (PDN), which may facilitate the flow of power throughout the stack. The PDN may include circuitry and components configured to transfer power throughout the stack of semiconductor dies, which may include one or more vias (e.g., through silicon vias (TSVs), back end of line (BEOL) vias) extending through portions of the stack of semiconductor dies. For example, the PDN may include multiple TSVs below multiple layers of respective metal pads, where each layer of the metal pads may be separated by a respective set of BEOL vias. In some examples, a resistance (e.g., an electrical resistance, a thermal resistance) associated with the PDN may be based on one or more parameters associated with the circuitry of the PDN. For example, the resistance of the PDN may be based on a size of the TSVs (e.g., larger TSVs may be associated with increased resistance), a pitch of the TSVs (e.g., a smaller pitch of larger TSVs may be associated with increased resistance), or both, among other examples. The PDN may be relatively sensitive to resistance, such that increased resistivity may lead to increased heat in the stack of semiconductor dies. It may be challenging for the stack of semiconductor dies to dissipate heat during operation or manufacturing (e.g., in the case of increased thermal resistivity), which may lead to poor electrical performance during operations (e.g., in the case of increased electrical resistivity), among other examples, which may degrade operations at the stack of semiconductor dies. Thus, techniques may be desired to reduce the resistance of the PDN in the stack of semiconductor dies while enabling the pitch between components of the PDN circuitry to be scaled (e.g., to a reduced pitch).

In accordance with techniques described herein, the stack of semiconductor dies may include various structures of a PDN, each associated with a reduced resistance (e.g., increased thermal conductivity, increased electrical conductivity) relative to other PDN structures. For example, the PDN may include multiple TSVs having a relatively small footprint (e.g., a 1 μm diameter) coupled with a metallic pad, where the TSVs may have a relatively small pitch between adjacent ones of the TSVs (e.g., a 2 μm pitch). In some examples, the PDN structure may include layers between the multiple TSVs and the metallic pad, where each metal layer may be separated by a respective set of vias including various conductive materials. For example, the PDN structure may include respective sets of copper vias between each metal layer to couple the multiple TSVs with the metallic pad. Additionally, or alternatively, the PDN structure may include a set of tungsten vias between the metallic pad and a top metal layer (e.g., in addition to the copper vias between remaining layers). In such examples, another set of vias may couple the metallic pad to one or more hybrid bonding pads (e.g., to couple the PDN with another die, such as a logic die).

In some other examples, the PDN structure may include a single via (e.g., a through dielectric via (TDV)), where a bottom end of the single via may couple with the multiple TSVs and a top end of the single via may couple with the one or more hybrid bonding pads. In some other examples, the PDN structure may include multiple metallic pads above the multiple TSVs with respective sets of metal bars separating each metallic pad. In such examples, respective sets of multiple metallic pads and sets of metal bars may be coupled with individual ones of the multiple TSVs, or a single set of multiple metallic pads and sets of metal bars may extend across and couple with two or more of the multiple TSVs. Such techniques may reduce resistance associated with the PDN, which may improve overall operation of the PDN to supply power to one or more dies of the stack of semiconductor dies.

In addition to applicability in memory systems as described herein, techniques for low resistance structures may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving PDN performance in electronic devices, which may improve performance of the electronic devices and improve user experience, among other benefits.

In addition to applicability in memory systems as described herein, techniques for low resistance structures may be generally implemented to support edge computing applications. Edge computing is a distributed computing paradigm that brings computation and data storage closer to the sources of data than traditional cloud services. As the use of edge computing to provide computing, storage, and networking services at locations that are geographically closer to end users increases, many devices and systems may benefit from improved processing, performance, and storage at edge devices. For example, increasing memory density, capacity, and processing power of edge devices may decrease a reliance on the devices to remote computing or devices, which may otherwise increase latency of operations performed at the devices. Implementing the techniques described herein may support edge computing techniques by improving PDN performance in electronic devices, among other benefits.

Features of the disclosure are illustrated and described in the context of systems and architectures. Features of the disclosure are further illustrated and described in the context of devices.

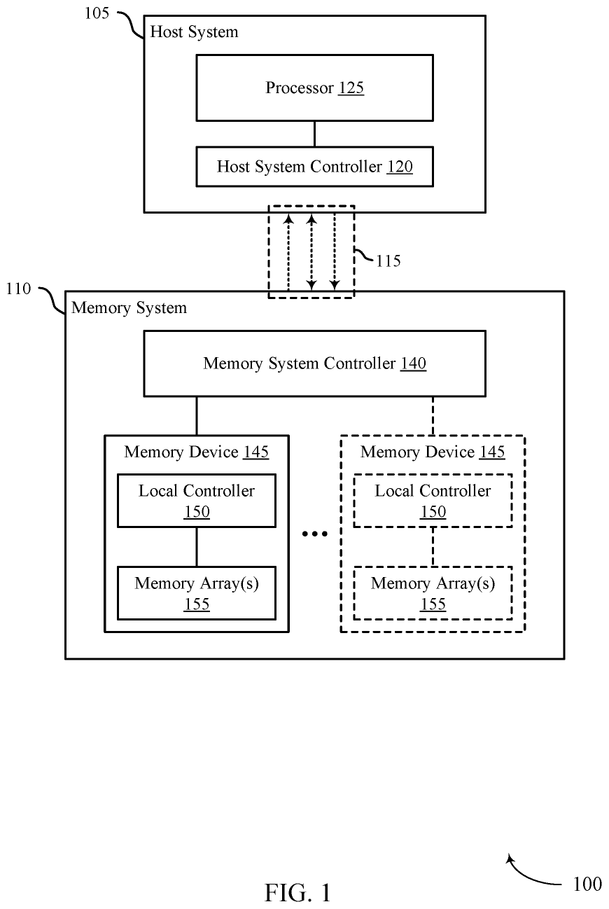

FIG. 1 shows an example of a system 100 that supports low resistance structures in systems in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, DRAM cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of a system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies (e.g., one or more memory stacks). In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies).

For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks. In some examples, multiple semiconductor dies of a memory system 110 or of a system 100 (e.g., an HBM system including aspects of a memory system 110, a DRAM system including aspects of a memory system 110 and a host system 105) may include one or more array dies stacked with a logic die (e.g., that includes aspects of the host system 105, that is coupled with another die that includes the host system 105) that includes interface blocks operable to access a set of memory arrays 155 distributed across the one or more second dies.

In some examples, the stack of semiconductor dies may include a PDN, which may facilitate the flow of power throughout the stack. The PDN may include circuitry and components configured to transfer power throughout the stack of semiconductor dies, which may include one or more vias (e.g., TSVs, BEOL vias) extending through portions of the stack of semiconductor dies. For example, the PDN may include multiple TSVs below multiple layers of respective metal pads, where each layer of the metal pads may be separated by a respective set of BEOL vias. In some examples, a resistance (e.g., an electrical resistance, a thermal resistance) associated with the PDN may be based on one or more parameters associated with the circuitry of the PDN. For example, the resistance of the PDN may be based on a size of the TSVs (e.g., larger TSVs may be associated with increased resistance), a pitch of the TSVs (e.g., a smaller pitch may be associated with increased resistance), or both, among other examples. The PDN may be relatively sensitive to resistance, such that increased resistivity may lead to increased heat in the stack of semiconductor dies. The additional heat in the stack of semiconductor dies may be challenging to dissipate during operation or manufacturing (e.g., in the case of increased thermal resistivity). The additional heat may lead to poor electrical performance during operations (e.g., in the case of increased electrical resistivity), among other examples, which may degrade operations at the stack of semiconductor dies. Thus, techniques may be desired to reduce the resistance of the PDN in the stack of semiconductor dies while enabling the pitch between components of the PDN circuitry to be scaled (e.g., to a reduced pitch).

In accordance with techniques described herein, the stack of semiconductor dies may include various structures of a PDN, each associated with a reduced resistance (e.g., increased thermal conductivity, increased electrical conductivity) relative to other PDN structures. For example, the PDN may include multiple TSVs having a relatively small footprint (e.g., a 1 μm diameter) coupled with a metallic pad, where the TSVs may have a relatively small pitch between adjacent ones of the TSVs (e.g., a 2 μm pitch). In some examples, the PDN structure may include layers between the multiple TSVs and the metallic pad, where each metal layer may be separated by a respective set of vias including various conductive materials. For example, the PDN structure may include respective sets of copper vias between each metal layer to couple the multiple TSVs with the metallic pad. Additionally, or alternatively, the PDN structure may include a set of tungsten vias between the metallic pad and a top metal layer (e.g., in addition to the copper vias between remaining layers). In such examples, another set of vias may couple the metallic pad to one or more hybrid bonding pads (e.g., to couple the PDN with another die, such as a logic die).

In some other examples, the PDN structure may include a single via (e.g., a TDV), where a bottom end of the single via may couple with the multiple TSVs and a top end of the single via may couple with the one or more hybrid bonding pads. In some other examples, the PDN structure may include multiple metallic pads above the multiple TSVs with respective sets of metal bars separating each metallic pad. In such examples, respective sets of multiple metallic pads and sets of metal bars may be coupled with individual ones of the multiple TSVs, or a single set of multiple metallic pads and sets of metal bars may extend across and couple with two or more of the multiple TSVs. Such techniques may reduce resistance associated with the PDN, which may improve overall operation of the PDN to supply power to one or more dies of the stack of semiconductor dies.

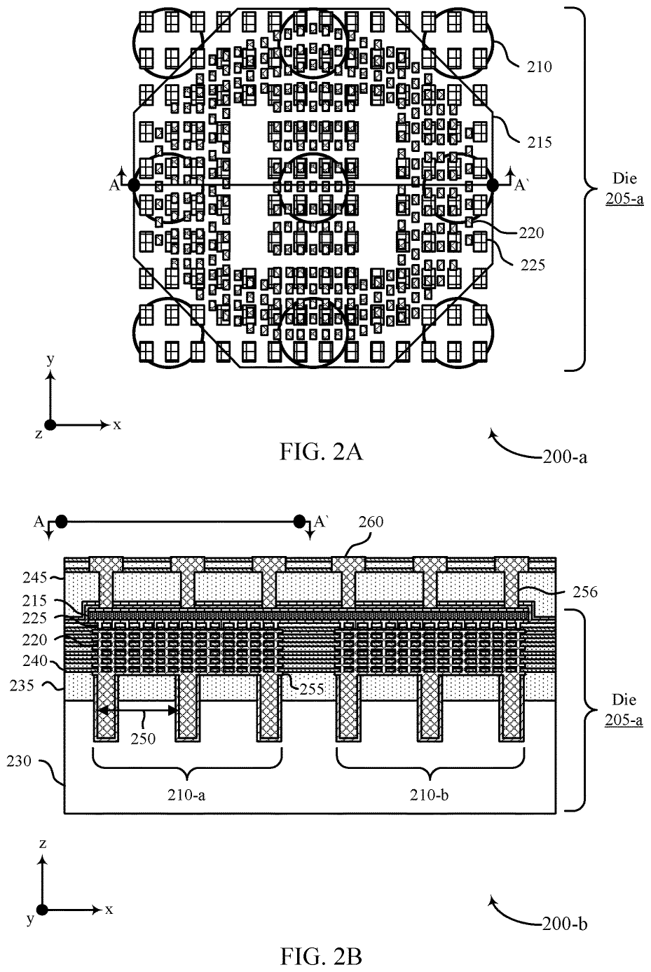

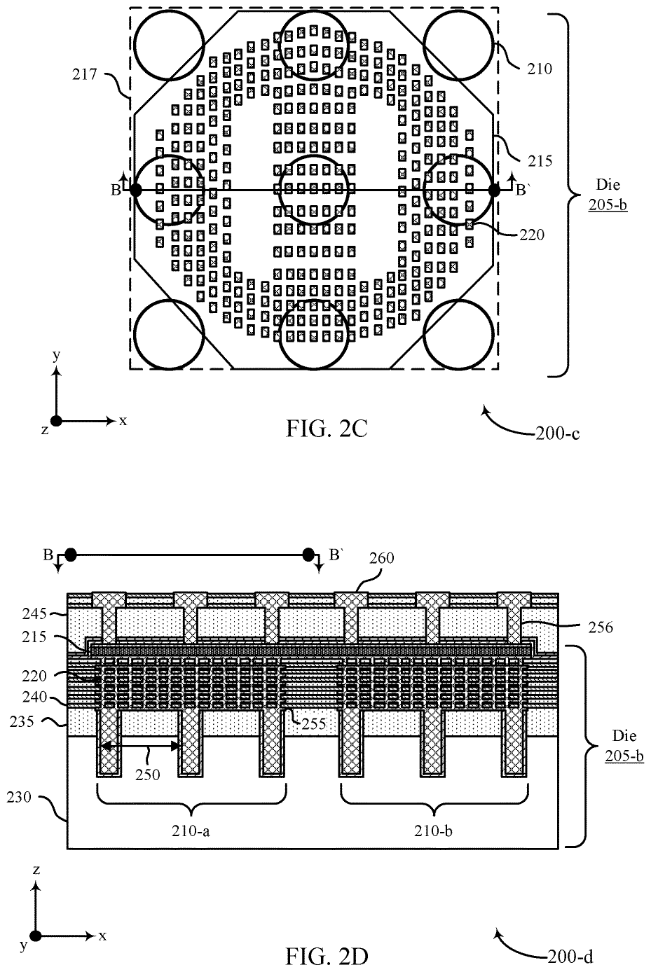

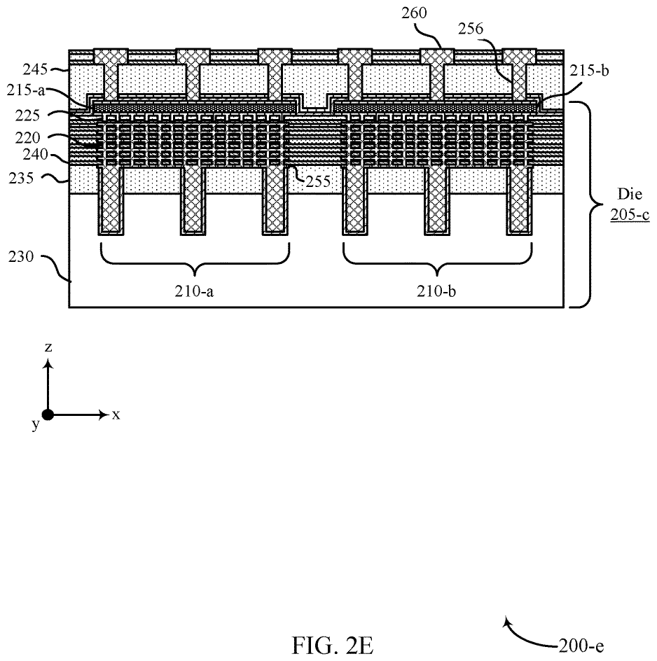

FIGS. 2A through 2E show examples of devices 200 that support low resistance structures in systems in accordance with examples as disclosed herein. The devices 200 may be examples of portions of system, such as the system 100 described with reference to FIG. 1. FIGS. 2A through 2E show various views and examples of a device 200 including circuitry having a structure that supports reduced resistance. For example, the devices 200 may illustrate examples of a PDN associated with a die 205 of a stacked semiconductor system and configured to provide power to one or more dies of the stacked semiconductor system (e.g., circuit dies, logic dies, memory dies, a combination of one or more dies). As described herein, the die 205 may be an example of a DRAM die, which may be a logic die (e.g., a GPU) that is over (e.g., and coupled with) one or more memory dies (not shown). In some other examples, the die 205 may be an example of an HBM die, which may be a logic die (e.g., GPU) that is under (e.g., and coupled with) one or more memory dies (not shown).

In some cases, the devices 200 may support multiple TSVs 210 coupled with a metallic pad 215, where the multiple TSVs 210 may be associated with a relatively small pitch (e.g., a 2 μm pitch between orthogonally adjacent ones of the TSVs 210), such that resistance associated with the PDN is reduced. For illustrative purposes, aspects of the devices described herein may be described with reference to an x-direction, a y-direction, and a z-direction of the illustrated coordinate systems. For example, devices 200-a and 200-c illustrate the device from a top-down view, where a substrate of the device may be associated with an xy-plane, and where the device extends a distance along the z-direction. Additionally, the devices 200-b, 200-d, and 200-e illustrate the device with a cross-sectional view, such that a portion of the memory architecture may be removed from the trimetric view to illustrate a cross-section of the memory architecture in the xz-plane. Although the devices 200 illustrate examples of relative dimensions and quantities of various features, aspects of the devices 200 may be implemented with other relative dimensions or quantities of such features in accordance with examples as disclosed herein. Additionally, while the devices 200 are described as including components having various metal materials, the devices 200 are not limited to the examples described herein and may include components having any suitable metal material.

FIG. 2A illustrates an example of a device 200-a that supports low resistance structures. The device 200-a may show a bird's eye view (e.g., a top-down view) of a PDN structure included in or associated with a die 205-a (e.g., a circuit die), which may be an example of a DRAM die. Components of the PDN structure shown in the device 200-a may be located at various layers or depths within a semiconductor stack including the device 200-a. For example, the device 200-a may include a set of multiple TSVs 210 coupled with a metallic pad 215 (e.g., an aluminum pad), where the TSVs 210 may be located beneath the metallic pad 215. In the example illustrated by the device 200-a, the PDN structure may further include vias 220 (e.g., copper vias) and vias 225 (e.g., tungsten vias) located between and coupling the TSVs 210 and the metallic pad 215. For example, respective sets of the vias 220 may separate multiple metal pads 255 between the TSVs 210 and the metallic pad 215 and a set of the vias 225 may be located between a top metal pad 255 of the multiple metal pads 255 and the metallic pad 215. As described herein, the device 200-a may include any quantity of the vias 220 and any quantity of the vias 225.

In some examples, parameters associated with the TSVs 210 may be configured to support reduced resistance associated with the PDN structure. For example, a diameter (e.g., a footprint in the xy-plane) of each TSV 210 may be relatively small, such as a 1 μm diameter, and a pitch of the TSVs 210 may be relatively small, such as a 2 μm pitch. In some cases, by including multiple smaller TSVs 210 below the metallic pad 215 and having reduced pitch may reduce resistance at the PDN and improve power transfer performance at the die 205-a.

FIG. 2B illustrates an example of a device 200-b that supports low resistance structures. The device 200-b shows a cross-sectional view of the device 200-a in the xz-plane relative to the A-A′ line shown in FIG. 2A. As shown in the device 200-b, the die 205-a may include a silicon material 230, a first dielectric material 235 over the silicon material 230, multiple layers 240 (e.g., semiconductor layers including silicon carbon nitride (SiCN), layers that support low thermal resistance (K)) over the first dielectric material 235, and a second dielectric material 245 over the multiple layers 240.

In the example of the device 200-b, the die 205-a may include the multiple TSVs 210 (e.g., a set of TSVs 210-a, a set of TSVs 210-b) extending into the silicon material 230 (e.g., a DRAM portion of the die 205-a) and extending into the first dielectric material 235. In some examples, a respective top end of each of the TSVs 210 may couple with a first metal pad 255 of multiple metal pads 255 (e.g., a bottom layer of the metal pads 255). The metal pads 255 may be separated by respective sets of the vias 220, which may be arranged in a lattice or grid structure (e.g., layers of the vias 220 between the metal pads 255 with portions of the vias 220 extending through the layers 240). In the example illustrated by the device 200-b, a set of the vias 225 may be located between and may couple a second metal pad 255 of the metal pads 255 (e.g., a top layer of the metal pads 255) with the metallic pad 215. In some examples, a set of vias 256 may couple with the metallic pad 215 and respective bond pads 260 (e.g., hybrid bond pads) to electrically connect the die 205-a with another die 205 of the semiconductor stack.

In some examples, the die 205-a may include one or more sets of TSVs 210. In the example shown by FIG. 2B, the die 205-a may include a set of TSVs 210-a corresponding to a cross-section of the A-A′ line illustrated in FIG. 2A (e.g., the set of TSVs 210-a may correspond to a central row of TSVs 210 shown in FIG. 2A). Additionally, or alternatively, the die 205-a may include a set of TSVs 210-b (not shown in FIG. 2A) coupled with the metallic pad 215 by circuitry including the metal pads 255 separated by respective second sets of vias 220 and a second set of vias 225. In the example of the device 200-b, the TSVs 210-a and the TSVs 210-b may each be coupled with the metallic pad 215 by respective sets of vias 220, metal pads 255, and vias 225 (e.g., respective portions of BEOL circuitry). In some examples, a set of multiple TSVs 210 may be coupled with an aluminum pad (e.g., the metallic pad 215 via the metal pads 255, the vias 225, and/or the vias 225) and the aluminum pad may couple with one or more bond pads (e.g., bond pads 260, hybrid bond pads). For example, a TSV 210 may include (e.g., be made of, or otherwise be) a copper bonding pad coupled with a copper pillar, where a first end of the copper pillar may be coupled with the aluminum pad and a second end of the copper pillar (opposite the first end) may be coupled with the copper bonding pad.

In some cases, the TSVs 210 of the device 200-b (e.g., the set of TSVs 210-a and the set of TSVs 210-b) may be associated with a relatively small pitch. For example, a distance 250 between a first side of a first TSV 210 and a first side of a second TSV 210 adjacent to the first TSV 210 may be 2 μm. Such a pitch may support multiple TSVs 210 being coupled with a single metallic pad 215, which may reduce resistance associated with a PDN included in or associated with the die 205-a and improve performance of the PDN.

FIG. 2C illustrates an example of a device 200-c that supports low resistance structures. The device 200-c illustrates a bird's eye view (e.g., a top-down view) of a PDN structure included in or associated with a die 205-b (e.g., a circuit die), which may be an example of a DRAM die. The die 205-b may include a PDN structure similar to the PDN structure of the die 205-a, including TSVs 210, a metallic pad 215 (and/or a metallic pad 217), and vias 220 (e.g., copper vias) that separate metal pads 255 (e.g., copper pads) and are between the TSVs 210 and the metallic pad 215 (e.g., BEOL circuitry). In some examples, the device 200-c may include a metallic pad 215 having an octagonal shape (e.g., similar to the metallic pad 215 illustrated in FIG. 2A), may include a metallic pad 217 having a square shape, or both. The techniques described herein may be applicable to devices including one or both of the octagonal metallic pad 215 and the square metallic pad 217. In some examples, a diameter of the TSVs 210 may be relatively small (e.g., a 1 μm diameter in the xy-plane) and a pitch between the TSVs 210 may be relatively small (e.g., a 2 μm pitch between orthogonally adjacent TSVs 210), which may support reduced resistance associated with the PDN included in or associated with the die 205-b. In some examples, the BEOL circuitry (e.g., respective sets of the vias 220 between multiple metal pads 255) between the TSVs 210 and the metallic pad 215 may not include tungsten vias (e.g., the vias 225 illustrated and described with reference to FIGS. 2A and 2B), which may further reduce the resistance associated with the PDN.

FIG. 2D illustrates an example of a device 200-d that supports low resistance structures. The device 200-d shows a cross-sectional view of the device 200-c in the xz-plane relative to the B-B′ line shown in FIG. 2C. As shown in the device 200-d, the die 205-b may have a similar structure to the die 205-a shown in FIG. 2B. For example, the die 205-b may include the silicon material 230, the first dielectric material 235 over the silicon material 230, the multiple layers 240 (e.g., semiconductor layers including SiCN, semiconductor layers that support reduced thermal resistance) over the first dielectric material 235, and the second dielectric material 245 over the multiple layers 240. In the example of the device 200-d, the die 205-b may include the multiple TSVs 210 (e.g., a set of TSVs 210-a, a set of TSVs 210-b) extending into the silicon material 230 (e.g., a DRAM portion of the die 205-b) and extending into the first dielectric material 235. The device 200-d may include multiple vias 256 extending through the second dielectric material 245 to couple the metallic pad 215 with respective bond pads 260 (e.g., hybrid bond pads) to electrically connect the die 205-b with another die 205 of the semiconductor stack.

In the example of the device 200-d, each of the metal pads 255 may be separated by respective sets of the vias 220 (e.g., copper vias) and a top metal pad 255 and the metallic pad 215 may be separated by a set of the vias 220 (e.g., in place of the vias 225 in the example of the die 205-a, by copper vias). Additionally, each of the set of TSVs 210-a and the set of TSVs 210-b may be coupled with the metallic pad 215 by respective portions of BEOL circuitry including the metal pads 255 and respective sets of the vias 220.

In some cases, the TSVs 210 of the device 200-d (e.g., the set of TSVs 210-a and the set of TSVs 210-b) may be associated with a relatively small pitch. For example, a distance 250 between a first side of a first TSV 210 and a first side of a second TSV 210 adjacent to the first TSV 210 may be 2 μm. Such a pitch may support multiple TSVs 210 being coupled with a single metallic pad 215, which may reduce resistance associated with a PDN included in or associated with the die 205-b and improve performance of the PDN.

FIG. 2E illustrates an example of a device 200-e that supports low resistance structures. The device 200-e may be an example of a cross-sectional view (e.g., in the xz-plane) of a die 205-c that may include or be associated with a PDN structure. For example, the die 205-c may be an example of the die 205-a or the die 205-b, and may include the silicon material 230, the first dielectric material 235 over the silicon material 230, the multiple layers 240 over the first dielectric material 235, and the second dielectric material 245 over the multiple layers 240. The die 205-c may include the multiple TSVs 210 (e.g., a set of TSVs 210-a, a set of TSVs 210-b) extending into the silicon material 230 (e.g., a DRAM portion of the die 205-c) and extending into the first dielectric material 235. In the example shown by the device 200-e, the die 205-c may include respective metallic pads 215 associated with the sets of TSVs 210. For example, a metallic pad 215-a may couple with the set of TSVs 210-a via first BEOL circuitry and a metallic pad 215-b may couple with the set of TSVs 210-b via second BEOL circuitry. The first BEOL circuitry and the second BEOL circuitry may each include metal pads 255 separated by respective sets of vias, which may include the vias 220 (e.g., as described with reference to the die 205-a) or may include both the vias 220 and the vias 225 (e.g., as described with reference to the die 205-b). Additionally, or alternatively, respective sets of vias 256 may couple the metallic pad 215-a and the metallic pad 215-b to respective sets of bond pads 260 (e.g., hybrid bond pads) to electrically connect the die 205-c with another die 205 of the semiconductor stack.

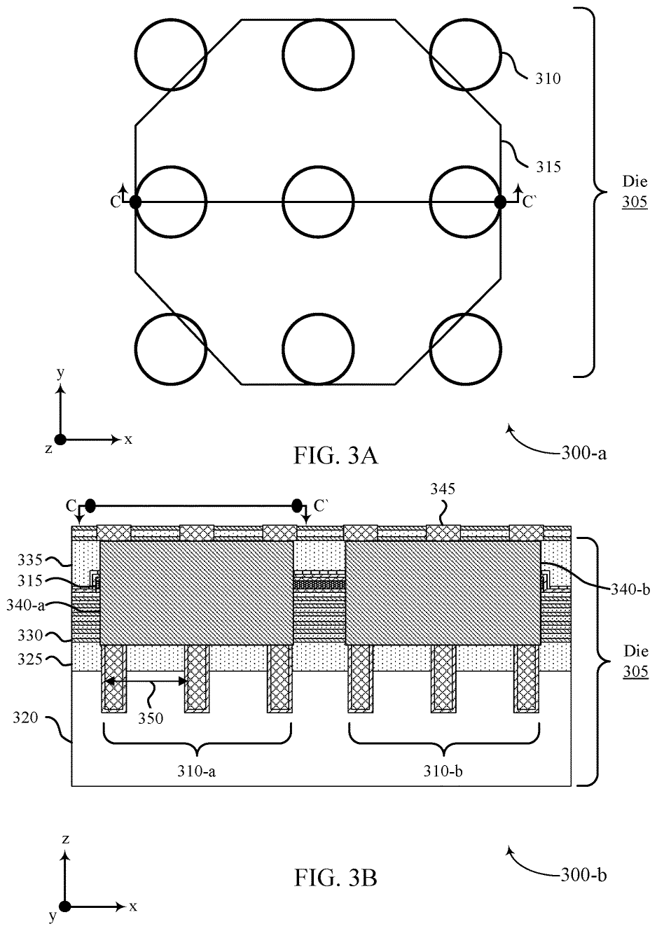

FIGS. 3A and 3B show examples of devices 300 that support low resistance structures in systems in accordance with examples as disclosed herein. The devices 300 may be examples of portions of a system, such as the system 100 described with reference to FIG. 1. FIGS. 3A and 3B show various views of an example of a device 300 including circuitry having a structure that supports reduced resistance. For example, the devices 300 may illustrate examples of a PDN associated with a die 305 of a stacked semiconductor system and configured to provide power to one or more dies of the stacked semiconductor system (e.g., circuit dies, logic dies, memory dies, a combination of one or more dies). In some cases, the devices 300 may support multiple TSVs 310 coupled with a metallic pad 315, where the multiple TSVs 310 may be associated with a relatively small pitch (e.g., a 2 μm pitch between orthogonally adjacent ones of the TSVs 310), such that resistance associated with the PDN is reduced. As described herein, the die 305 may be an example of a DRAM die, which may be a logic die (e.g., a GPU) that is over (e.g., and coupled with) one or more memory dies (not shown). In some other examples, the die 305 may be an example of an HBM die, which may be a logic die (e.g., GPU) that is under (e.g., and coupled with) one or more memory dies (not shown).

FIG. 3A illustrates an example of a device 300-a that supports low resistance structures. The device 300-a may show a bird's eye view (e.g., a top-down view in the xy-plane) of a PDN structure included in or associated with a die 305 (e.g., a circuit die, a logic die), which may be an example of a DRAM die. Components of the PDN structure shown in the device 300-a may be located at various layers or depths within a semiconductor stack including the device 300-a. For example, the device 300-a may include a set of multiple TSVs 310 and a metallic pad 315 (e.g., an aluminum pad), where the TSVs 310 may be located beneath the metallic pad 315. In some examples, the die 305 may include a TDV configured to couple the TSVs 310 with the metallic pad 315. For example, the die 305 may include the TDV in place of BEOL circuitry included in the dies 205 described with reference to FIGS. 2A through 2E. In some examples, the TSVs 310 may be structured to support reduced resistance at the PDN. For example, a diameter of each of the TSVs 310 may be relatively small (e.g., a 1 μm diameter) and a pitch between orthogonally adjacent ones of the TSVs 310 may be relatively small (e.g., a 2 μm pitch).

FIG. 3B illustrates an example of a device 300-b that supports low resistance structures. The device 300-b may show a cross-sectional view of the device 300-a in the xz-plane relative to the C-C′ line shown in FIG. 3A. As shown in the example of the device 300-b, the die 305 may include a silicon material 320, a first dielectric material 325 over the silicon material 320, one or more layers 330 (e.g., semiconductor layers including SiCN, semiconductor layers that support relatively lower thermal resistance) over the first dielectric material 325, and a second dielectric material 335 over the one or more layers 330. The die 305 may include the multiple TSVs 310 extending between a portion of the silicon material 320 (e.g., a DRAM portion of the die 305) and a portion of the first dielectric material 325. In some cases, the die 305 may include one or more TDVs 340 extending between the TSVs 310 and one or more bonding pads 345. For example, the die 305 may include sets of the TSVs 310 (e.g., a set of TSVs 310-a and a set of TSVs 310-b) coupled with respective TDVs 340 (e.g., the set of TSVs 310-a may couple with a TDV 340-a and the set of TSVs 310-b may couple with a TDV 340-b).

In some cases, a first side of the TDVs 340 may couple with a respective set of TSVs 310 and a second side of the TDVs 340 may couple with a respective set of bonding pads 345 to electrically connect the die 305 with another die 305 of the semiconductor stack. Additionally, or alternatively, the second side of the TDVs 340 may couple with the metallic pad 315 to couple the TSVs 310 with the metallic pad 315. In some examples, a pitch between the TSVs 310 of the die 305 may be configured to be relatively small. For example, a distance 350 between a first side of a first TSV 310 and a first side of a second TSV 310 adjacent to the first TSV 310 may be 2 μm. In some cases, by coupling multiple TSVs 310 to a single TDV 340, a resistance associated with the PDN may be reduced, thereby improving performance of the PDN.

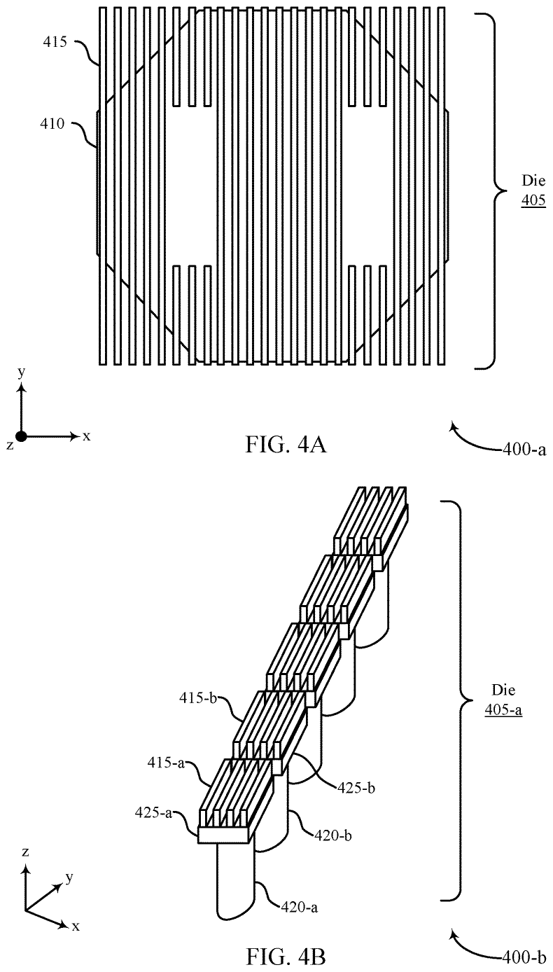

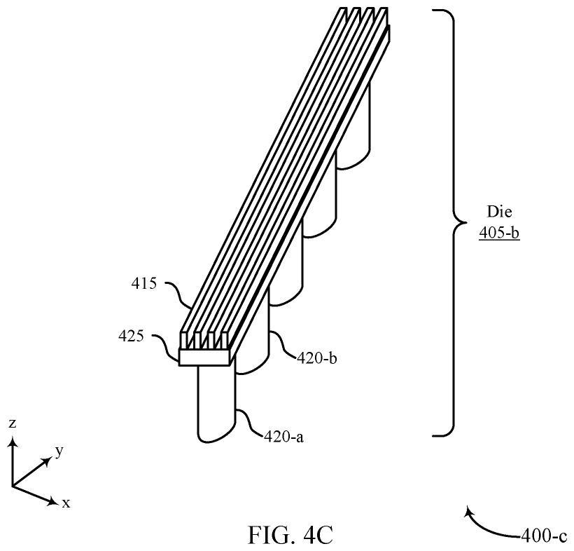

FIGS. 4A through 4C show examples of devices 400 that support low resistance structures in systems in accordance with examples as disclosed herein. The devices 400 may be examples of portions of system, such as the system 100 described with reference to FIG. 1. FIGS. 4A through 4C show various views and examples of a device 400 including circuitry having a structure that supports reduced resistance. For example, the devices 400 may illustrate examples of a PDN associated with a die 405 of a stacked semiconductor system and configured to provide power to one or more dies of the stacked semiconductor system (e.g., circuit dies, logic dies, memory dies, a combination of one or more dies). In some cases, the devices 400 may support multiple TSVs coupled with a metallic pad 410, where the multiple TSVs may be associated with a relatively small pitch (e.g., a 2 μm pitch between orthogonally adjacent ones of the TSVs), such that resistance associated with the PDN is reduced. As described herein, the die 405 may be an example of a DRAM die, which may be a logic die (e.g., a GPU) that is over (e.g., and coupled with) one or more memory dies (not shown). In some other examples, the die 405 may be an example of an HBM die, which may be a logic die (e.g., GPU) that is under (e.g., and coupled with) one or more memory dies (not shown).

FIG. 4A illustrates an example of a device 400-a that supports low resistance structures. The device 400-a may show a bird's eye view (e.g., a top-down view in the xy-plane) of a PDN structure included in or associated with a die 405 (e.g., a circuit die, a logic die, a memory device), which may be an example of a DRAM die. Components of the PDN structure shown in the device 400-a may be located at various layers or depths within a semiconductor stack including the device 400-a. For example, the device 400-a may include a metallic pad 410 (e.g., an aluminum pad) and a set of multiple metal bars 415 below the metallic pad 410, where each set of multiple metal bars 415 may separate a respective metallic pad (e.g., copper pads, not shown).

In some examples, the device 400-a may include multiple TSVs located below a first metallic pad of the multiple metallic pads (e.g., a bottom metallic pad), where a diameter of each of the TSVs may be relatively small (e.g., 1 μm diameter) and a pitch between orthogonally adjacent ones of the TSVs may be relatively small (e.g., a 2 μm pitch), which may support reduced resistance associated with the PDN. In some examples, a top metallic pad of the multiple metallic pads may couple with the metallic pad 410 (e.g., either directly or through one or more vias), where one or more second vias may couple the metallic pad 410 with another die of the semiconductor stack to electrically connect the die 405 with the other die of the semiconductor stack.

FIG. 4B illustrates an example of a device 400-b that supports low resistance structures. The device 400-b may show an isometric view of the device 400-a, such that portions of the device 400-a are shown in the x, y, and z directions. In some cases, the device 400-b may include a die 405-a (e.g., a circuit die), which may be an example of the die 405 described with reference to FIG. 4A. In the example of the device 400-b, the die 405-a may include one or more TSVs 420 coupled with respective sets of PDN circuitry. For example, the die 405-a may include a first TSV 420-a coupled with a first metallic pad 425-a (e.g., copper pad) and a first set of metal bars 415-a and may include a second TSV 420-b coupled with a second metallic pad 425-b and a second set of metal bars 415-b. In some examples, each metal bar 415 associated with a respective metallic pad 425 may extend along a length of the corresponding metallic pad 425. In some examples, the PDN circuitry of each TSV 420 of the die 405-a may be coupled with multiple layers of metallic pads 425 separated by respective sets of metal bars 415 (not shown) along the z-direction. For example, the metallic pad 425-a may be an example of a first metallic pad coupled with the TSV 420-a, where one or more additional metallic pads 425 and sets of metal bars 415 may be located (e.g., in alternating layers) above the metal bars 415-a.

In some examples, a second metallic pad 425 above the TSV 420-a corresponding to a top metallic pad may couple directly with the metallic pad 410 (e.g., a metallic pad coupled with multiple TSVs 420 via respective stacks of PDN circuitry). Additionally, or alternatively, a set of metallic bars 415 above the second metallic pad may couple the metallic pad 410 with the second metallic pad 425. In some examples, a set of vias may be coupled with the metallic pad 410, where such a set of vias may be used to couple the die 405-a with another die of the semiconductor stack. In some examples, the TSVs 420 may be configured to reduced resistance associated with the PDN of the die 405-a. For example, a diameter of each of the TSVs 420 may be relatively small (e.g., 1 μm diameter) and a pitch between orthogonally adjacent ones of the TSVs 420 may be relatively small (e.g., a 2 μm pitch between the TSV 420-a and the TSV 420-b) to support reduced resistance associated with the PDN.

FIG. 4C illustrates an example of a device 400-c that supports low resistance structures. The device 400-c may show an isometric view of the device 400-a, such that portions of the device 400-a are shown in the x, y, and z directions. In some cases, the device 400-c may include a die 405-b (e.g., a circuit die), which may be an example of the die 405 described with reference to FIG. 4A. In the example of the device 400-c, the die 405-b may include PDN circuitry coupled with multiple TSVs 420. For example, a TSV 420-a and a TSV 420-b may each couple with a metallic pad 425 (e.g., the metallic pad 425 may extend across multiple TSVs 420 of the die 405-b) that is coupled with a set of metal bars 415 (e.g., which may extend across a length of the metallic pad 425). Additionally, the PDN circuitry may include multiple metallic pads 425 stacked (e.g., in the z-direction) above the TSVs 420 separated by respective sets of metal bars 415 (not shown). In some cases, a top metallic pad 425 of the multiple metallic pads 425 may couple with the metal pad 410 (e.g., either directly or via a set of metal bars 415), where the metal pad 410 may be coupled with a set of vias configured to couple the metal pad 410 with another die of the semiconductor stack (e.g., to electrically connect the PDN of the die 405-b with the other die). In some examples, the die 405-b may include second PDN circuitry coupled with a second set of TSVs 420 (e.g., a second set of TSVs 420 within another portion of the die 405-b), where the second PDN circuitry may facilitate coupling between the second set of TSVs 420 and the metal pad 410. Such PDN structures may reduce resistance associated with the PDN and improve overall performance of the PDN.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 1: A circuit die, including: a first via; a plurality of metallic pads, where a first metallic pad of the plurality of metallic pads is coupled with the first via; a respective set of metal bars separating each metallic pad of the plurality of metallic pads, and where each metal bar of the respective set of metal bars extends along a length of a corresponding metallic pad; and an aluminum pad coupled with a second metallic pad of the plurality of metallic pads.

Aspect 2: The circuit die of aspect 1, further including: a second via; a second plurality of metallic pads, where a first metallic pad of the second plurality of metallic pads is coupled with the second via, and where a second metallic pad of the second plurality of metallic pads is coupled with the aluminum pad; and a respective set of second metal bars separating each metallic pad of the second plurality of metallic pads, and where each second metal bar of the respective set of second metal bars extends along a length of a corresponding metallic pad of the second plurality of metallic pads.

Aspect 3: The circuit die of aspect 2, where a distance between a first side of the first via and a first side of the second via is two micrometers.

Aspect 4: The circuit die of any of aspects 2 through 3, where a diameter of the first via and the second via is one micrometer.

Aspect 5: The circuit die of any of aspects 1 through 4, further including: a silicon material, a first dielectric material over the silicon material, one or more layers over the first dielectric material, and a second dielectric material over the one or more layers.

Aspect 6: The circuit die of aspect 5, where the first via extends from the silicon material through the first dielectric material to a start of the one or more layers, the plurality of metallic pads and the respective sets of metal bars are stacked through the one or more layers, and the aluminum pad is formed in the second dielectric material and over the one or more layers.

Aspect 7: The circuit die of any of aspects 1 through 6, further including: a plurality of second vias each coupled with the aluminum pad, where a second die is coupled with the circuit die via the plurality of second vias.

Aspect 8: The circuit die of any of aspects 1 through 7, where the circuit die is configured as a logic die, and the first via, the plurality of metallic pads, and the respective sets of metal bars include a PDN for the logic die.

Aspect 9: The circuit die of any of aspects 1 through 8, where the circuit die is configured as a memory device.

An apparatus is described. The following provides an overview of aspects of the apparatus as described herein:

Aspect 10: A circuit die, including: a plurality of vias; a plurality of metallic pads, where a first metallic pad of the plurality of metallic pads is coupled with each via of the plurality of vias; a respective set of metal bars separating each metallic pad of the plurality of metallic pads, and where each metal bar of the respective set of metal bars extends along a length of a corresponding metallic pad; and an aluminum pad coupled with a second metallic pad of the plurality of metallic pads.

Aspect 11: The circuit die of aspect 10, further including: a second plurality of vias; a second plurality of metallic pads, where a first metallic pad of the second plurality of metallic pads is coupled with each via of the second plurality of vias, and where a second metallic pad of the second plurality of metallic pads is coupled with the aluminum pad; and a respective set of second metal bars separating each metallic pad of the second plurality of metallic pads, and where each metal bar of the respective set of metal bars extends along a length of a corresponding metallic pad

Aspect 12: The circuit die of any of aspects 10 through 11, where a distance between a first side of a first via of the plurality of vias and a first side of a second via directly adjacent to the first via is two micrometers.

Aspect 13: The circuit die of any of aspects 10 through 12, where a diameter of each via of the plurality of vias is one micrometer.

Aspect 14: The circuit die of any of aspects 10 through 13, further including: a plurality of second vias each coupled with the aluminum pad, where a second die is coupled with the circuit die via the plurality of second vias.

Aspect 15: The circuit die of any of aspects 10 through 14, where the circuit die is configured as a logic die, and the plurality of vias, the plurality of metallic pads, and the respective sets of metal bars include a PDN for the logic die.

Aspect 16: The circuit die of any of aspects 10 through 15, where the circuit die is configured as a memory device.

An apparatus is described. The following provides an overview of aspects of the apparatus as described herein:

Aspect 17: A circuit die, including: a silicon material; a first dielectric material over the silicon material; one or more layers over the first dielectric material; a second dielectric material over the one or more layers; and a plurality of first vias, where each via of the plurality of first vias extends between a portion of the silicon material and a portion of the first dielectric material; and a second via, where a first side of the second via is coupled with each via of the plurality of first vias, and where the second via extends from the first dielectric material and through the one or more layers and the second dielectric material.

Aspect 18: The circuit die of aspect 17, further including: a plurality of third vias, where each via of the plurality of third vias extends between the portion of the silicon material and the portion of the first dielectric material; and a fourth via, where a first side of the fourth via is coupled with each via of the plurality of third vias, and where the fourth via extends from the first dielectric material and through the one or more layers and the second dielectric material.

Aspect 19: The circuit die of any of aspects 17 through 18, further including: a plurality of bonding pads coupled with a second side of the second via, the second side being opposite the first side.

Aspect 20: The circuit die of aspect 19, where a second die is coupled with the circuit die via the plurality of bonding pads.

Aspect 21: The circuit die of any of aspects 17 through 20, where the circuit die is configured as a logic die, and the plurality of first vias and the second via include a PDN for the logic die.

Aspect 22: The circuit die of any of aspects 17 through 21, where the circuit die is configured as a memory device.

An apparatus is described. The following provides an overview of aspects of the apparatus as described herein:

Aspect 23: A device, including: a first die including: a plurality of vias; a plurality of metallic pads, where a first metallic pad of the plurality of metallic pads is coupled with each via of the plurality of vias; and a respective set of vias separating each metallic pad of the plurality of metallic pads; and an aluminum pad coupled with a second metallic pad of the plurality of metallic pads.

Aspect 24: The device of aspect 23, where the first die further includes: a second plurality of vias, where the second plurality of vias couple the aluminum pad with the second metallic pad of the plurality of metallic pads, and where the second plurality of vias include tungsten.

Aspect 25: The device of any of aspects 23 through 24, where the first die further includes: a second plurality of vias; a second plurality of metallic pads, where a first metallic pad of the second plurality of metallic pads is coupled with each via of the second plurality of vias, and, where the aluminum pad is coupled with a second metallic pad of the second plurality of metallic pads; and a respective set of second vias separating each metallic pad of the second plurality of metallic pads.

Aspect 26: The device of any of aspects 23 through 25, where the first die further includes: a second plurality of vias; a second plurality of metallic pads, where a first metallic pad of the second plurality of metallic pads is coupled with each via of the second plurality of vias; a respective set of second vias separating each metallic pad of the second plurality of metallic pads; and a second aluminum pad coupled with a second metallic pad of the second plurality of metallic pads.

Aspect 27: The device of any of aspects 23 through 26, where the first die further includes: a second plurality of vias coupled with the aluminum pad, where a second die is coupled with the first die via the second plurality of vias.

Aspect 28: The device of any of aspects 23 through 27, where the first die is configured as a logic die, and the plurality of vias, the plurality of metallic pads, and the respective sets of vias include a PDN for the logic die.

Aspect 29: The device of any of aspects 23 through 28, where the device is configured as a memory device.

An apparatus is described. The following provides an overview of aspects of the apparatus as described herein:

Aspect 30: A memory device, including: a first die associated with PDN circuitry of the memory device, where the PDN circuitry includes: a first via; a plurality of metallic pads, where a first metallic pad of the plurality of metallic pads is coupled with a first via; a respective set of metal bars separating each metallic pad of the plurality of metallic pads, and where each metal bar of the respective set of metal bars extends along a length of a corresponding metallic pad; and a second metallic pad coupled with a second metallic layer of the plurality of metallic pads; and a second die coupled with the first die, where power is supplied to at least the second die via the PDN circuitry.

Aspect 31: A circuit die, including: a plurality of TSVs; an aluminum pad coupled with the plurality of TSVs; and one or more bonding pads coupled with the aluminum pad.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A circuit die, comprising:
a first via;
a plurality of metallic pads, wherein a first metallic pad of the plurality of metallic pads is coupled with the first via;
a respective set of metal bars separating each metallic pad of the plurality of metallic pads, and wherein each metal bar of the respective set of metal bars extends along a length of a corresponding metallic pad; and
an aluminum pad coupled with a second metallic pad of the plurality of metallic pads.

2. The circuit die of claim 1, further comprising:
a second via;
a second plurality of metallic pads, wherein a first metallic pad of the second plurality of metallic pads is coupled with the second via, and wherein a second metallic pad of the second plurality of metallic pads is coupled with the aluminum pad; and
a respective set of second metal bars separating each metallic pad of the second plurality of metallic pads, and wherein each second metal bar of the respective set of second metal bars extends along a length of a corresponding metallic pad of the second plurality of metallic pads.

3. The circuit die of claim 2, wherein a distance between a first side of the first via and a first side of the second via is two micrometers.

4. The circuit die of claim 2, wherein a diameter of the first via and the second via is one micrometer.

5. The circuit die of claim 1, further comprising:
a silicon material, a first dielectric material over the silicon material, one or more layers over the first dielectric material, and a second dielectric material over the one or more layers.

6. The circuit die of claim 5, wherein:
the first via extends from the silicon material through the first dielectric material to a start of the one or more layers,
the plurality of metallic pads and the respective sets of metal bars are stacked through the one or more layers, and
the aluminum pad is formed in the second dielectric material and over the one or more layers.

7. The circuit die of claim 1, further comprising:
a plurality of second vias each coupled with the aluminum pad, wherein a second die is coupled with the circuit die via the plurality of second vias.

8. The circuit die of claim 1, wherein:
the circuit die is configured as a logic die, and
the first via, the plurality of metallic pads, and the respective sets of metal bars comprise a power delivery network (PDN) for the logic die.

9. The circuit die of claim 1, wherein the circuit die is configured as a memory device.

10. A circuit die, comprising:
a plurality of vias;
a plurality of metallic pads, wherein a first metallic pad of the plurality of metallic pads is coupled with each via of the plurality of vias;
a respective set of metal bars separating each metallic pad of the plurality of metallic pads, and wherein each metal bar of the respective set of metal bars extends along a length of a corresponding metallic pad; and
an aluminum pad coupled with a second metallic pad of the plurality of metallic pads.

11. The circuit die of claim 10, further comprising:
a second plurality of vias;
a second plurality of metallic pads, wherein a first metallic pad of the second plurality of metallic pads is coupled with each via of the second plurality of vias, and wherein a second metallic pad of the second plurality of metallic pads is coupled with the aluminum pad; and
a respective set of second metal bars separating each metallic pad of the second plurality of metallic pads, and wherein each metal bar of the respective set of metal bars extends along a length of a corresponding metallic pad.

12. The circuit die of claim 10, wherein a distance between a first side of a first via of the plurality of vias and a first side of a second via directly adjacent to the first via is two micrometers.

13. The circuit die of claim 10, wherein a diameter of each via of the plurality of vias is one micrometer.

14. The circuit die of claim 10, further comprising:
a plurality of second vias each coupled with the aluminum pad, wherein a second die is coupled with the circuit die via the plurality of second vias.

15. The circuit die of claim 10, wherein:
the circuit die is configured as a logic die, and
the plurality of vias, the plurality of metallic pads, and the respective sets of metal bars comprise a power delivery network (PDN) for the logic die.

16. The circuit die of claim 10, wherein the circuit die is configured as a memory device.

17. A circuit die, comprising:
a silicon material;
a first dielectric material over the silicon material;
one or more layers over the first dielectric material;
a second dielectric material over the one or more layers;
a plurality of first vias, wherein each via of the plurality of first vias extends between a portion of the silicon material and a portion of the first dielectric material; and
a second via, wherein a first side of the second via is coupled with each via of the plurality of first vias, and wherein the second via extends from the first dielectric material and through the one or more layers and the second dielectric material.

18. The circuit die of claim 17, further comprising:
a plurality of third vias, wherein each via of the plurality of third vias extends between the portion of the silicon material and the portion of the first dielectric material; and
a fourth via, wherein a first side of the fourth via is coupled with each via of the plurality of third vias, and wherein the fourth via extends from the first dielectric material and through the one or more layers and the second dielectric material.

19. The circuit die of claim 17, further comprising:
a plurality of bonding pads coupled with a second side of the second via, the second side being opposite the first side.

20. The circuit die of claim 19, wherein a second die is coupled with the circuit die via the plurality of bonding pads.

21. The circuit die of claim 17, wherein:
the circuit die is configured as a logic die, and
the plurality of first vias and the second via comprise a power delivery network (PDN) for the logic die.

22. The circuit die of claim 17, wherein the circuit die is configured as a memory device.

23. A device, comprising:
a first die comprising:
a plurality of vias;
a plurality of metallic pads, wherein a first metallic pad of the plurality of metallic pads is coupled with each via of the plurality of vias;
a respective set of vias separating each metallic pad of the plurality of metallic pads; and
an aluminum pad coupled with a second metallic pad of the plurality of metallic pads.

24. The device of claim 23, wherein the first die further comprises:
a second plurality of vias, wherein the second plurality of vias couple the aluminum pad with the second metallic pad of the plurality of metallic pads, and wherein the second plurality of vias comprise tungsten.

25. The device of claim 23, wherein the first die further comprises:
a second plurality of vias;
a second plurality of metallic pads, wherein a first metallic pad of the second plurality of metallic pads is coupled with each via of the second plurality of vias, and, wherein the aluminum pad is coupled with a second metallic pad of the second plurality of metallic pads; and
a respective set of second vias separating each metallic pad of the second plurality of metallic pads.

26. The device of claim 23, wherein the first die further comprises:
a second plurality of vias;
a second plurality of metallic pads, wherein a first metallic pad of the second plurality of metallic pads is coupled with each via of the second plurality of vias;
a respective set of second vias separating each metallic pad of the second plurality of metallic pads; and
a second aluminum pad coupled with a second metallic pad of the second plurality of metallic pads.

27. The device of claim 23, wherein the first die further comprises:
a second plurality of vias coupled with the aluminum pad, wherein a second die is coupled with the first die via the second plurality of vias.

28. The device of claim 23, wherein:
the first die is configured as a logic die, and
the plurality of vias, the plurality of metallic pads, and the respective sets of vias comprise a power delivery network (PDN) for the logic die.

29. The device of claim 23, wherein the device is configured as a memory device.

30. A memory device, comprising:
a first die associated with power delivery network (PDN) circuitry of the memory device, wherein the PDN circuitry comprises:
a first via;
a plurality of metallic pads, wherein a first metallic pad of the plurality of metallic pads is coupled with a first via;
a respective set of metal bars separating each metallic pad of the plurality of metallic pads, and wherein each metal bar of the respective set of metal bars extends along a length of a corresponding metallic pad;
a second metallic pad coupled with a second metallic layer of the plurality of metallic pads; and
a second die coupled with the first die, wherein power is supplied to at least the second die via the PDN circuitry.

31. A circuit die, comprising:
a plurality of through silicon vias (TSVs);
an aluminum pad coupled with the plurality of TSVs; and
one or more bonding pads coupled with the aluminum pad.

32. The circuit die of claim 31, further comprising:
a plurality of metallic pads, wherein a first metallic pad of the plurality of metallic pads is coupled with each TSV of the plurality of TSVs and a second metallic pad is coupled with the aluminum pad; and
a respective set of vias separating each metallic pad of the plurality of metallic pads.

33. The circuit die of claim 31, further comprising:
a metallic pillar, wherein the one or more bonding pads are coupled with the aluminum pad based at least in part on a first end of the metallic pillar being coupled with the aluminum pad and a second end of the metallic pillar being coupled with the one or more bonding pads.

34. The circuit die of claim 31, further comprising:
a second plurality of TSVs; and
a second aluminum pad coupled with the second plurality of TSVs, wherein the one or more bonding pads are coupled with the second aluminum pad.
